(19) United States
(12) Patent Application Publication
(10) Pub. No.: US 2020/0203393 A1
(43) Pub. Date: Jun. 25, 2020

(54) ARRAY SUBSTRATE HAVING CAPACITOR AND METHOD FOR MANUFACTURING SAME

(71) Applicant: Junyan HU, Wuhan (CN)

(72) Inventor: Junyan HU, Wuhan (CN)

(21) Appl. No.: 16/482,254

(22) PCT Filed: Apr. 24, 2019
(86) PCT No.: PCT/CN2019/084039

§ 371 Date: Jul. 31, 2019

(30) Foreign Application Priority Data
Dec. 19, 2018 (CN) 201811560085.3

(51) Int. Cl. H01L 27/12; H01L 21/311; H01L 49/02; H01L 27/32

(52) U.S. Cl. CPC H01L 27/1255; H01L 27/1288; H01L 27/1248; H01L 21/31144; H01L 2227/323; H01L 27/3246; H01L 27/3265; H01L 27/3258; H01L 28/60

(57) ABSTRACT

The present disclosure provides an array substrate having a capacitor and a method for manufacturing the same. In the region where the scan line and the VDD power line overlap each other, a capacitor is established. Capacitance of the capacitor can be adjusted by adjusting the size of the overlapping area and the thickness of the interlayer dielectric layer sandwiched between two metal layers. The invention provided by the present disclosure simplifies the manufacturing process, increases the manufacturing efficiency and the manufacturing yield, reduces the manufacturing costs, and still saves the space required to accommodate the capacitor. Therefore, the invention provided by the present disclosure makes the products more competitive, and facilitates in development of displays having a high resolution.

### FIELD OF INVENTION

The present disclosure relates to a field of display technology, and more particularly to an array substrate having a capacitor and a method for manufacturing the same.

### BACKGROUND

Conventional flat panel displays include liquid crystal displays (LCDs) and organic light emitting diode displays (OLED displays). OLED displays have outstanding properties, including being light weight, being self-illuminating, having wide viewing angles, having low driving voltages, having high light-emitting efficiency, having low power consumption, and having a short response time, therefore OLED displays are widely used in various kinds of products. OLED displays are categorized to include passive matrix OLED displays (PM-OLED displays) and active matrix OLED displays (AM-OLED displays). According to prior art, an AM-OLED display includes two transistors and a storage capacitor sandwiched therebetween.

The storage capacitor is used to maintain electrical potential of a pixel electrode, and generally consists of a gate electrode of a driver thin film transistor (driver TFT), a second metal layer, and an insulation layer disposed therebetween.

Please refer to FIG. 1, which shows a cross-sectional view of a layered structure of an array substrate having a capacitor according to the prior art. The array substrate includes a substrate 11, a buffer layer (M/B) 112, a buffer layer 113, a first gate insulation layer (GI1) 114, a second gate insulation layer (GI2) 115, an interlayer dielectric layer (ILD) 116, a planarization layer (PLN) 117, an anode (ANO) 118, a pixel defining layer (PDL) 119, a photoresist layer (photo spacer, PS) 120, a thin film transistor (TFT), and a capacitor. The TFT includes an active layer (Act) 121 formed on the buffer layer 113, a first gate electrode layer (GE1) 122 formed on the first gate insulation layer 114, and a source/drain electrode (S/D) 123 formed on the interlayer dielectric layer (ILD) 116. The first gate electrode layer (GE1) 122 formed on the first gate insulation layer 114 and the second gate electrode layer (GE2) 124 formed on the second gate insulation layer 115 constitute the capacitor. Such a structural design not only reduces the space required to accommodate the capacitor but facilitates in development of displays having a high resolution. However, such a structural design also requires two depositions for the gate insulation layers (i.e., GI1 and GI2) and two depositions and patterning processes for the gate electrode layers (i.e., GE1 and GE2). This makes the manufacturing process complicated, and increases manufacturing costs.

Therefore, there is a need to provide an array substrate having a capacitor, where the manufacturing process thereof is simplified, the manufacturing costs thereof are reduced, and space usage is still maximized, to solve problems existing in prior art.

### SUMMARY OF DISCLOSURE

In order to solve the problems existing in prior art, the objective of the present disclosure is to provide an array substrate having a capacitor and a method for manufacturing the same in order to simplify the manufacturing process, reduce the manufacturing costs, and still saves the space required to accommodate the capacitor, so as to facilitate in development of displays having a high resolution.

To achieve the above said objective, the present disclosure provides a method for manufacturing an array substrate having a capacitor, comprising steps of: (1) providing a substrate, and sequentially forming a barrier layer, a buffer layer, and an active layer on the substrate; (2) sequentially depositing a gate insulation layer and a first metal layer on the active layer, and patterning the first metal layer to form a gate electrode and a scan line, wherein the scan line functions as a lower electrode plate of the capacitor; (3) depositing an interlayer dielectric layer on the first metal layer, and partially etching the interlayer dielectric layer using a halftone mask to form a source and drain electrode contact hole and a trench, wherein the source and drain electrode contact hole is formed at a position corresponding to two ends of the active layer, and the trench is formed at a position corresponding to the lower electrode plate of the capacitor; (4) depositing a second metal layer on the interlayer dielectric layer, and patterning the second metal layer to form a source and drain electrode and a power line, wherein the source and drain electrode is electrically connected to the active layer via the source and drain electrode contact hole, the power line is formed within the trench and functions as an upper electrode plate of the capacitor, and the lower electrode plate of the capacitor and the upper electrode plate of the capacitor are insulated from each other by the interlayer dielectric layer; and (5) sequentially forming a planarization layer, an anode, a pixel defining layer, and a photoresist layer on the second metal layer.

To achieve the above said objective, the present disclosure additionally provides a method for manufacturing an array substrate having a capacitor, comprising steps of: (1) providing a substrate, and sequentially forming a barrier layer, a buffer layer, and an active layer on the substrate; (2) sequentially depositing a gate insulation layer and a first metal layer on the active layer, and patterning the first metal layer to form a gate electrode and a scan line, wherein the scan line functions as a lower electrode plate of the capacitor; (3) depositing an interlayer dielectric layer on the first metal layer, and patterning the interlayer dielectric layer to form a source and drain electrode contact hole, wherein the source and drain electrode contact hole is formed at a position corresponding to two ends of the active layer; (4) depositing a second metal layer on the interlayer dielectric layer, and patterning the second metal layer to form a source and drain electrode and a power line, wherein the source and drain electrode is electrically connected to the active layer via the source and drain electrode contact hole, the power line functions as an upper electrode plate of the capacitor, and the lower electrode plate of the capacitor and the upper electrode plate of the capacitor are insulated from each other by the interlayer dielectric layer; and (5) sequentially forming a planarization layer, an anode, a pixel defining layer, and a photoresist layer on the second metal layer.

To achieve the above said objective, the present disclosure further provides an array substrate having a capacitor, comprising: a substrate; a barrier layer, a buffer layer, and an active layer sequentially disposed on the substrate; a gate insulation layer disposed on the active layer, wherein the gate insulation layer covers the active layer; a gate electrode and a lower electrode plate of the capacitor disposed on the gate insulation layer; an interlayer dielectric layer disposed on the gate electrode and the lower electrode plate of the capacitor, wherein the interlayer dielectric layer covers the gate electrode and the lower electrode plate of the capacitor; a source and drain electrode and an upper electrode plate of the capacitor disposed on the interlayer dielectric layer, wherein the source and drain electrode is electrically connected to the active layer via a source and drain electrode contact hole, and the lower electrode plate of the capacitor and the upper electrode plate of the capacitor are insulated from each other by the interlayer dielectric layer; a planarization layer, an anode, a pixel defining layer, and a photoresist layer sequentially disposed on the source and drain electrode and the upper electrode plate of the capacitor.

The present disclosure provides the following beneficial effects. In the region where the scan line and the VDD power line overlap each other, a capacitor is established. Capacitance of the capacitor can be adjusted by adjusting the size of the overlapping area and the thickness of the interlayer dielectric layer sandwiched between two metal layers. With use of a halftone mask which partially etches the interlayer dielectric layer, the thickness of the interlayer dielectric layer in the capacitor region is reduced and thus capacitance of the capacitor is increased without affecting the thickness of the interlayer dielectric layer in other regions. Compared to prior art, the method for manufacturing an array substrate having a capacitor provided by the present disclosure simplifies the manufacturing process, increases the manufacturing efficiency and the manufacturing yield, reduces the manufacturing costs, and still saves the space required to accommodate the capacitor. Therefore, the method provided by the present disclosure makes the products more competitive, and facilitates in development of displays having a high resolution.

### BRIEF DESCRIPTION OF DRAWINGS

To detailedly explain the technical schemes of the embodiments or existing techniques, drawings that are used to illustrate the embodiments or existing techniques are provided. Apparently, the illustrated embodiments are just a part of those of the present disclosure. It is easy for any person having ordinary skill in the art to obtain other drawings without labor for inventiveness.

FIG. 1 shows a cross-sectional view of a layered structure of an array substrate having a capacitor according to the prior art.

FIG. 2 is a schematic diagram showing a flowchart of a method for manufacturing an array substrate having a capacitor according to the present disclosure.

FIGS. 3A-3F shows each stage in a process flow of a method for manufacturing an array substrate having a capacitor according to the present disclosure.

FIG. 4 shows a cross-sectional view of a layered structure of an array substrate having a capacitor according to the present disclosure.

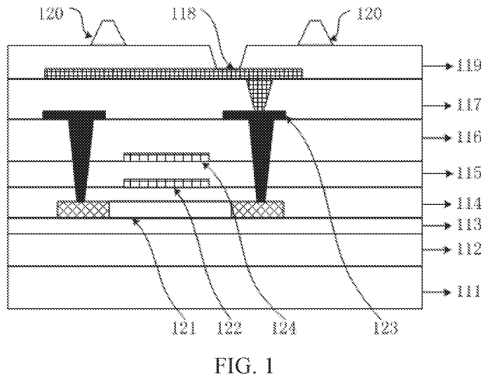

### DETAILED DESCRIPTION

The embodiments of the present invention will be described in detail below with reference to the accompanying drawings in which same or similar reference numerals indicate the same or similar elements, or elements with same or similar function. The embodiments described below with reference to the accompanying drawings are exemplary and are merely used to explain the present invention, but should not be construed as limiting the present invention.

In the present disclosure, unless specified and limited otherwise, a first feature “on” or “below” a second feature may include that the first feature is in direct contact with the second feature, and may also include that the first feature and the second feature are not in direct contact with each other, but are contacted via an additional feature formed therebetween. Furthermore, the first feature “on,” “above,” or “on top of” a second feature may include that the first feature is right or obliquely “on,” “above,” or “on top of” the second feature, or just means that the first feature is at a height higher than that of the second feature. The first feature “below,” “under,” or “on bottom of” the second feature may include that the first feature is right or obliquely “below,” “under,” or “on bottom of” the second feature, or just means that the first feature is at a height lower than that of the second feature.

Various embodiments and examples are provided in the following description to implement different structures of the present disclosure. In order to simplify the present disclosure, certain elements and settings will be described. However, these elements and settings are only by way of example and are not intended to limit the present disclosure. In addition, reference numerals may be repeated in different examples in the present disclosure. This repeating is for the purpose of simplification and clarity and does not refer to relations between different embodiments and/or settings. Furthermore, examples of different processes and materials are provided in the present disclosure. However, it would be appreciated by those skilled in the art that other processes and/or materials may be also applied.

The present disclosure provides an array substrate having a capacitor and a method for manufacturing the same. In the region where the scan line and the VDD power line overlap each other, a capacitor is established (That is, the wirings of the scan line and the VDD power line are used to constitute a capacitor). Capacitance of the capacitor can be adjusted by adjusting the size of the overlapping area and the thickness of the interlayer dielectric layer sandwiched between two metal layers. With use of a halftone mask which partially etches the interlayer dielectric layer, the thickness of the interlayer dielectric layer in the capacitor region is reduced and thus capacitance of the capacitor is increased without affecting the thickness of the interlayer dielectric layer in other regions. Compared to prior art, the method for manufacturing an array substrate having a capacitor provided by the present disclosure simplifies the manufacturing process, increases the manufacturing efficiency and the manufacturing yield, reduces the manufacturing costs, and still saves the space required to accommodate the capacitor. Therefore, the method provided by the present disclosure makes the products more competitive, and facilitates in development of displays having a high resolution.

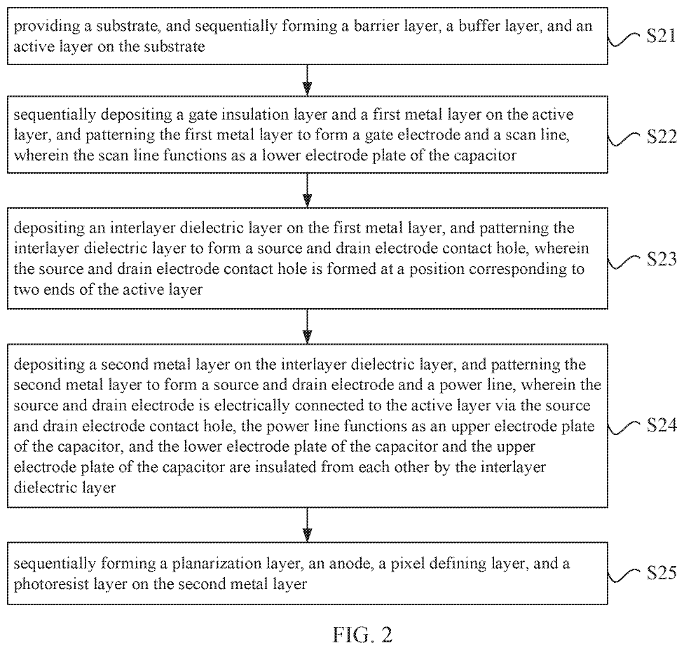

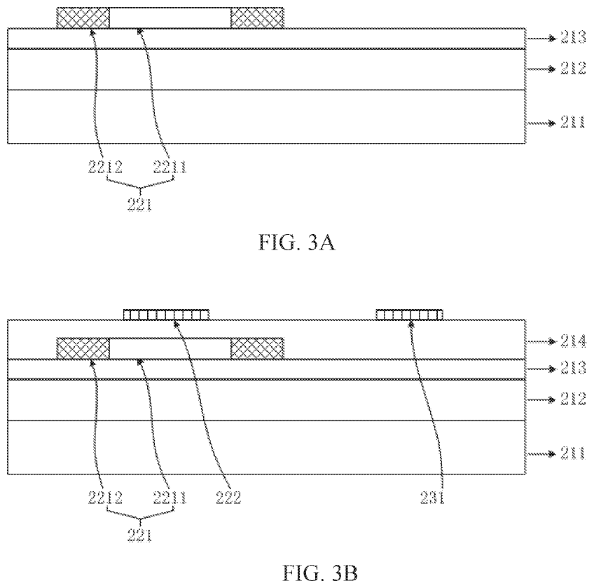

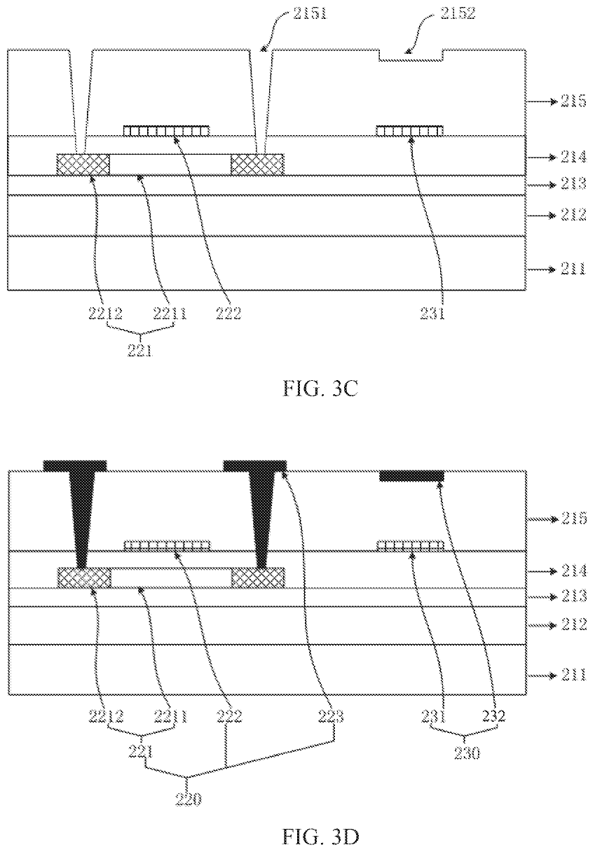

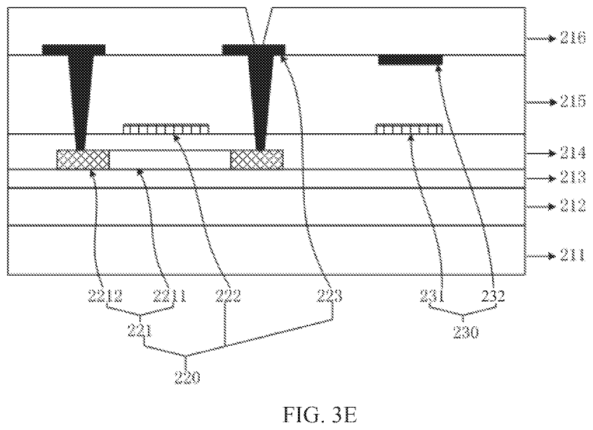

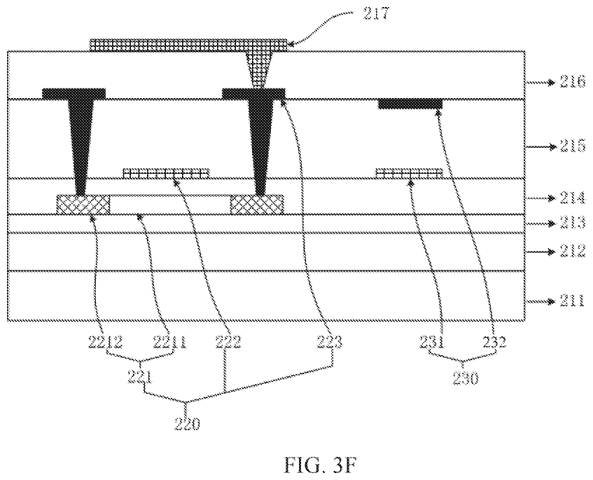

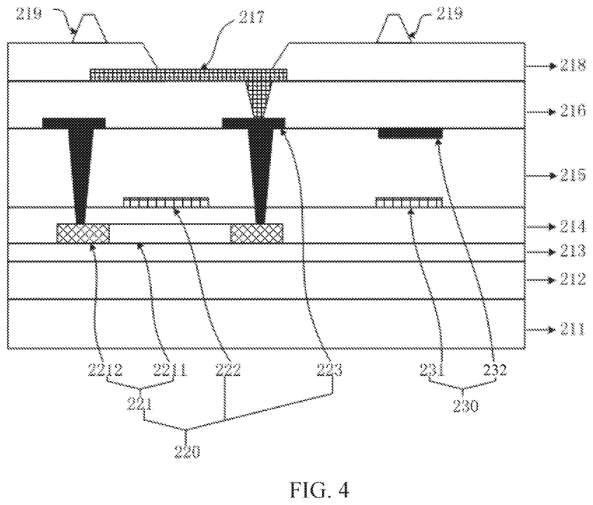

Please refer to FIG. 2, FIGS. 3A-3F, and FIG. 4. FIG. 2 is a schematic diagram showing a flowchart of a method for manufacturing an array substrate having a capacitor according to the present disclosure. FIGS. 3A-3F shows each stage in a process flow of a method for manufacturing an array substrate having a capacitor according to the present disclosure. FIG. 4 shows a cross-sectional view of a layered structure of an array substrate having a capacitor according to the present disclosure. The method includes a step S21 of providing a substrate, and sequentially forming a barrier layer, a buffer layer, and an active layer on the substrate; a step S22 of sequentially depositing a gate insulation layer and a first metal layer on the active layer, and patterning the first metal layer to form a gate electrode and a scan line, wherein the scan line functions as a lower electrode plate of the capacitor; a step S23 of depositing an interlayer dielectric layer on the first metal layer, and patterning the interlayer dielectric layer to form a source and drain electrode contact hole, wherein the source and drain electrode contact hole is formed at a position corresponding to two ends of the active layer; a step S24 of depositing a second metal layer on the interlayer dielectric layer, and patterning the second metal layer to form a source and drain electrode and a power line, wherein the source and drain electrode is electrically connected to the active layer via the source and drain electrode contact hole, the power line functions as an upper electrode plate of the capacitor, the lower electrode plate of the capacitor and the upper electrode plate of the capacitor are insulated from each other by the interlayer dielectric layer; and a step S25 of sequentially forming a planarization layer, an anode, a pixel defining layer, and a photoresist layer on the second metal layer. The description of this method provided by the present disclosure is detailed below.

In the step S21, a substrate is provided, and a barrier layer, a buffer layer, and an active layer are sequentially formed on the substrate. Please also refer to FIG. 2 and FIG. 3A, in which FIG. 3A shows that a barrier layer, a buffer layer, and an active layer are sequentially formed on the substrate according to one embodiment of the present disclosure. The substrate 211 can be a glass substrate or a flexible substrate made of a flexible material, polyimide (PI). Specifically, a substrate 211 is provided. A barrier layer (M/B) 212 is deposited on the substrate 211. A buffer layer 213 is formed on the barrier layer 212. An active layer (Act) 221 of a thin film transistor (TFT) 220 is formed on the buffer layer 213. The active layer 221 is deposited on the buffer layer 213, and the active layer 221 is crystalized and patterned, such that the active layer 221 includes a polysilicon area 2211 and a source and drain electrode contact area 2212 disposed at two ends of the polysilicon area 2211.

In the step S22, a gate insulation layer and a first metal layer are sequentially deposited on the active layer, and the first metal layer is patterned to form a gate electrode and a scan line, wherein the scan line functions as a lower electrode plate of the capacitor. Please also refer to FIG. 2 and FIG. 3B, in which FIG. 3B shows that a gate electrode and a scan line are formed according to one embodiment of the present disclosure. Specifically, a first metal layer deposited on the gate insulation layer (GI1) 214 is patterned, so as to form a gate electrode (GE1) 222 and a scan line 231. The gate electrode 222 is disposed above the polysilicon area 2211 of the active layer 221. The scan line 231 functions as a lower electrode plate 231 of the capacitor 230. In other words, the gate electrode 222 and the lower electrode plate 231 of the capacitor 230 are formed at the same time and are disposed at a same layer. (Both are disposed above the gate insulation layer 214.)

The first metal layer can be made of titanium, aluminum, molybdenum, or copper, and have a thickness ranging from 1000 Å to 5000 Å. The lower electrode plate 231 of the capacitor 230 can be made of titanium, aluminum, molybdenum, or copper, and have a thickness ranging from 1000 Å to 5000 Å.

In the step S23, an interlayer dielectric layer is deposited on the first metal layer, and the interlayer dielectric layer is patterned to form a source and drain electrode contact hole, wherein the source and drain electrode contact hole is formed at a position corresponding to two ends of the active layer. Please also refer to FIG. 2 and FIG. 3C, in which FIG. 3C shows that an interlayer dielectric layer is deposited and patterned according to one embodiment of the present disclosure. Specifically, in the embodiment of FIG. 3C, a halftone mask is used to partially etch the interlayer dielectric layer (ILD) 215, so as to form a source and drain electrode contact hole 2151 and a trench 2152 in the interlayer dielectric layer 215. The bottom of the source and drain electrode contact hole 2151 is located on the source and drain electrode contact area 2212 of the active layer 221. The trench 2152 is formed at a position corresponding to the scan line 231 (i.e., the lower electrode plate 231 of the capacitor 230). In other words, the interlayer dielectric layer of the capacitor 230 is constructed by the remaining interlayer dielectric layer located under the trench 2152. Formation of the trench 2152 is one preferred embodiment provided by the present disclosure, where formation of the trench 2152 facilitates in reducing the thickness of the interlayer dielectric layer in the capacitor region and increasing capacitance of the capacitor. In other embodiment, the interlayer dielectric layer 215 can include solely the source and drain electrode contact hole 2151.

The interlayer dielectric layer 215 is made of silicon nitride (SiNₓ), silicon dioxide (SiO₂), or a combination of silicon nitride and silicon dioxide. By forming the trench 2152 in the interlayer dielectric layer 215, the thickness of the interlayer dielectric layer in the capacitor region can be reduced and capacitance of the capacitor can be increased without affecting the thickness of the interlayer dielectric layer in other regions. In addition, with use of a halftone mask, the depth of the trench 2152 can be adjusted and the thickness of the remaining interlayer dielectric layer located under the trench 2152 can be adjusted, such that capacitance of the capacitor can be increased or decreased. Preferably, the remaining interlayer dielectric layer located under the trench 2152 has a thickness ranging from 500 Å to 6000 Å. That is, the thickness of the interlayer dielectric layer between the upper electrode plate and the lower electrode plate of the capacitor 230 has a thickness ranging from 500 Å to 6000 Å.

In the step S24, a second metal layer is deposited on the interlayer dielectric layer, and the second metal layer is patterned to form a source and drain electrode and a power line, wherein the source and drain electrode is electrically connected to the active layer via the source and drain electrode contact hole, the power line functions as an upper electrode plate of the capacitor, the lower electrode plate of the capacitor and the upper electrode plate of the capacitor are insulated from each other by the interlayer dielectric layer. Please also refer to FIG. 2 and FIG. 3D, in which FIG. 3D shows that the source and drain electrode and the power line are formed according to one embodiment of the present disclosure. Specifically, a second metal layer is deposited on the interlayer dielectric layer 215, and the second metal layer is patterned to form a source and drain electrode (S/D) 224 and a power line 232. The source and drain electrode 223 is electrically connected to the active layer 221 via the source and drain electrode contact hole 2151. (Specifically, the source and drain electrode 223 is electrically connected to the source and drain electrode contact area 2212 of the active layer 221 via the source and drain electrode contact hole 2151.) The power line 232 functions as an upper electrode plate 232 of the capacitor 230 of the array substrate. The lower electrode plate 231 of the capacitor 230 and the upper electrode plate 232 of the capacitor 230 are insulated from each other by the interlayer dielectric layer 215. In the present embodiment, the upper electrode plate 232 of the capacitor 230 is formed within the trench 2152 in the interlayer dielectric layer 215. In other embodiments, the source and drain electrode 223 and the upper electrode plate 232 of the capacitor 230 are formed at the same time and are disposed at a same layer. (Both are disposed above the interlayer dielectric layer 215.)

The second metal layer can be made of titanium, aluminum, molybdenum, or copper, and have a thickness ranging from 1000 Å to 5000 Å. That is, the upper electrode plate 232 of the capacitor 230 can be made of titanium, aluminum, molybdenum, or copper, and have a thickness ranging from 1000 Å to 5000 Å.

To this stage, formation of the capacitor 230 of the array substrate is completed. The lower electrode plate 231 of the capacitor 230 consists of the scan line 231 formed by the first metal layer, which can be made of titanium, aluminum, molybdenum, or copper, and have a thickness ranging from 1000 Å to 5000 521 . The upper electrode plate 232 of the capacitor 230 consists of the VDD power line 232 formed by the second metal layer, which can be made of titanium, aluminum, molybdenum, or copper, and have a thickness ranging from 1000 Å to 5000 Å. The interlayer dielectric layer of the capacitor 230 consists of the remaining interlayer dielectric layer 215 located under the trench 2152, which can be made of silicon nitride, silicon dioxide, or a combination of silicon nitride and silicon dioxide, and have a thickness ranging from 500 Å to 6000 Å that is adjustable using a halftone mask. Capacitance of the capacitor 230 can be adjusted by adjusting the size of the overlapping area of the scan line and the VDD power line and by adjusting the depth of the trench 2152.

In the step S25, a planarization layer, an anode, a pixel defining layer, and a photoresist layer are sequentially formed on the second metal layer. Please also refer to FIG. 2, FIGS. 3E-3F, and FIG. 4. FIG. 3E shows that a planarization layer is formed according to one embodiment of the present disclosure. FIG. 3F shows that an anode is formed according to one embodiment of the present disclosure. FIG. 4 shows a cross-sectional view of a layered structure of an array substrate according to one embodiment of the present disclosure.

Specifically, as shown in FIG. 3E, an organic layer is coated on the source and drain electrode 223 and the power line 232 above the interlayer dielectric layer 215, and is patterned to form the planarization layer (PLZ) 216.

Specifically, as shown in FIG. 3F, an anode metal layer (PE) is deposited on the planarization layer 216, and is patterned to form the anode (ANO) 217. The anode 217 is disposed above the source and drain electrode 223 and is electrically connected to the source and drain electrode 223.

Specifically, an organic photoresist layer is coated on the anode 217, and is patterned to form the pixel defining layer (PDL) 218 and the photoresist layer (photo spacer, PS) 219. To this stage, formation of the array substrate of the present disclosure is completed, and a cross-sectional view thereof is shown in FIG. 4.

The present disclosure provides a method for manufacturing an array substrate having a capacitor. In the region where the scan line and the VDD power line overlap each other, a capacitor is established. Capacitance of the capacitor can be adjusted by adjusting the size of the overlapping area and the thickness of the interlayer dielectric layer sandwiched between two metal layers. With use of a halftone mask which partially etches the interlayer dielectric layer, the thickness of the interlayer dielectric layer in the capacitor region is reduced and thus capacitance of the capacitor is increased without affecting the thickness of the interlayer dielectric layer in other regions. Compared to prior art, the method for manufacturing an array substrate having a capacitor provided by the present disclosure simplifies the manufacturing process, increases the manufacturing efficiency and the manufacturing yield, reduces the manufacturing costs, and still saves the space required to accommodate the capacitor. Therefore, the method provided by the present disclosure makes the products more competitive, and facilitates in development of displays having a high resolution.

Please refer to FIG. 4, which shows a cross-sectional view of a layered structure of an array substrate having a capacitor according to the present disclosure. The array substrate includes: a substrate 211; a barrier layer 212, a buffer layer 213, and an active layer 221 sequentially disposed on the substrate 211; a gate insulation layer 214 disposed on the active layer 221; a gate electrode 222 and a lower electrode plate 231 of the capacitor 23 disposed on the gate insulation layer 214; an interlayer dielectric layer 215 disposed on the gate electrode 222 and the lower electrode plate 231 of the capacitor 230; a source and drain electrode 223 and an upper electrode plate 232 of the capacitor 230 disposed on the interlayer dielectric layer 215, wherein the source and drain electrode 224 is electrically connected to the active layer 221 via a source and drain electrode contact hole 2151; and a planarization layer 216, an anode 217, a pixel defining layer 218, and a photoresist layer 219 sequentially disposed on the source and drain electrode 223 and the upper electrode plate 232 of the capacitor 230. The gate insulation layer 214 covers the active layer 221. The interlayer dielectric layer 215 covers the gate electrode 222 and the lower electrode plate 231 of the capacitor 230. The lower electrode plate 231 of the capacitor 230 and the upper electrode plate 232 of the capacitor 230 are insulated from each other by the interlayer dielectric layer 215.

Specifically, the active layer 221 includes a polysilicon area 2211 and a source and drain electrode contact area 2212 disposed at two ends of the polysilicon area 2211. The bottom of the source and drain electrode contact hole 2151 is located on the source and drain electrode contact area 2212 of the active layer 221. The source and drain electrode 223 is electrically connected to the source and drain electrode contact area 2212 of the active layer 221 via the source and drain electrode contact hole 2151.

Specifically, the lower electrode plate 231 of the capacitor 230 consists of the scan line formed at the same time as the gate electrode 222. The lower electrode plate 231 can be made of titanium, aluminum, molybdenum, or copper, and have a thickness ranging from 1000 Å to 5000 Å. The upper electrode plate 232 of the capacitor 230 consists of the VDD power line formed at the same time as the source and drain electrode 223. The upper electrode plate 232 can be made of titanium, aluminum, molybdenum, or copper, and have a thickness ranging from 1000 Å to 5000 Å. The interlayer dielectric layer of the capacitor 230 consists of the interlayer dielectric layer 215 sandwiched between the scan line and the VDD power line. The interlayer dielectric layer 215 can be made of silicon nitride, silicon dioxide, or a combination of silicon nitride and silicon dioxide, and have a thickness ranging from 500 Å to 6000 Å. Capacitance of the capacitor 230 can be adjusted by adjusting the size of the overlapping area of the scan line and the VDD power line.

Preferably, in the present embodiment, a trench 2152 is included in the interlayer dielectric layer 215 at a position corresponding to the lower electrode plate 231 of the capacitor 230. The upper electrode plate 232 of the capacitor 230 is disposed within the trench 2152. The interlayer dielectric layer of the capacitor 230 is constructed by the remaining interlayer dielectric layer located under the trench 2152. The trench 2152 can be formed at the same time as the source and drain electrode contact hole 2151, and a depth of the trench 2152 can be adjusted using a halftone mask. As such, capacitance of the capacitor 230 can be adjusted by adjusting the size of the overlapping area of the scan line and the VDD power line and by adjusting the depth of the trench 2152.

The present disclosure provides an array substrate. In the region where the scan line and the VDD power line overlap each other, a capacitor is established. Capacitance of the capacitor can be adjusted by adjusting the size of the overlapping area and the thickness of the interlayer dielectric layer sandwiched between two metal layers. With use of a halftone mask which partially etches the interlayer dielectric layer, the thickness of the interlayer dielectric layer in the capacitor region is reduced and thus capacitance of the capacitor is increased without affecting the thickness of the interlayer dielectric layer in other regions. The method for manufacturing an array substrate having a capacitor provided by the present disclosure simplifies the manufacturing process, increases the manufacturing efficiency and the manufacturing yield, reduces the manufacturing costs, and still saves the space required to accommodate the capacitor. Therefore, the method provided by the present disclosure makes the products more competitive, and facilitates in development of displays having a high resolution.

### INDUSTRIAL APPLICABILITY

The inventions provided by the present disclosure can be made and used in industry, and thus possess industrial applicability.

What is claimed is:

1. A method for manufacturing an array substrate having a capacitor, comprising steps of:
(1) providing a substrate, and sequentially forming a barrier layer, a buffer layer, and an active layer on the substrate;
(2) sequentially depositing a gate insulation layer and a first metal layer on the active layer, and patterning the first metal layer to form a gate electrode and a scan line, wherein the scan line functions as a lower electrode plate of the capacitor;
(3) depositing an interlayer dielectric layer on the first metal layer, and partially etching the interlayer dielectric layer using a halftone mask to form a source and drain electrode contact hole and a trench, wherein the source and drain electrode contact hole is formed at a position corresponding to two ends of the active layer, and the trench is formed at a position corresponding to the lower electrode plate of the capacitor;
(4) depositing a second metal layer on the interlayer dielectric layer, and patterning the second metal layer to form a source and drain electrode and a power line, wherein the source and drain electrode is electrically connected to the active layer via the source and drain electrode contact hole, the power line is formed within the trench and functions as an upper electrode plate of the capacitor, and the lower electrode plate of the capacitor and the upper electrode plate of the capacitor are insulated from each other by the interlayer dielectric layer; and
(5) sequentially forming a planarization layer, an anode, a pixel defining layer, and a photoresist layer on the second metal layer.

2. The method for manufacturing the array substrate having the capacitor according to claim 1, wherein both the lower electrode plate of the capacitor and the upper electrode plate of the capacitor have a thickness ranging from 1000 Å to 5000 Å.

3. The method for manufacturing the array substrate having the capacitor according to claim 1, wherein the interlayer dielectric layer between the lower electrode plate of the capacitor and the upper electrode plate of the capacitor has a thickness ranging from 500 Å to 6000 Å.

4. The method for manufacturing the array substrate having the capacitor according to claim 1, wherein the first metal layer and the second metal layer are made of titanium, aluminum, molybdenum, or copper.

5. The method for manufacturing the array substrate having the capacitor according to claim 1, wherein the interlayer dielectric layer is made of silicon nitride, silicon dioxide, or a combination of silicon nitride and silicon dioxide.

6. The method for manufacturing the array substrate having the capacitor according to claim 1, wherein in the step (5), sequentially forming the planarization layer, the anode, the pixel defining layer, and the photoresist layer on the second metal layer further comprises:
coating an organic layer on the second metal layer and patterning the organic layer to form the planarization layer;
depositing an anode metal layer on the planarization layer and patterning the anode metal layer to form the anode; and
coating an organic photoresist layer on the anode and patterning the organic photoresist layer to form the pixel defining layer and the photoresist layer.

7. A method for manufacturing an array substrate having a capacitor, comprising steps of:
(1) providing a substrate, and sequentially forming a barrier layer, a buffer layer, and an active layer on the substrate;
(2) sequentially depositing a gate insulation layer and a first metal layer on the active layer, and patterning the first metal layer to form a gate electrode and a scan line, wherein the scan line functions as a lower electrode plate of the capacitor;
(3) depositing an interlayer dielectric layer on the first metal layer, and patterning the interlayer dielectric layer to form a source and drain electrode contact hole, wherein the source and drain electrode contact hole is formed at a position corresponding to two ends of the active layer;
(4) depositing a second metal layer on the interlayer dielectric layer, and patterning the second metal layer to form a source and drain electrode and a power line, wherein the source and drain electrode is electrically connected to the active layer via the source and drain electrode contact hole, the power line functions as an upper electrode plate of the capacitor, and the lower electrode plate of the capacitor and the upper electrode plate of the capacitor are insulated from each other by the interlayer dielectric layer; and
(5) sequentially forming a planarization layer, an anode, a pixel defining layer, and a photoresist layer on the second metal layer.

8. The method for manufacturing the array substrate having the capacitor according to claim 7, wherein in the step (3), patterning the interlayer dielectric layer further comprises partially etching the interlayer dielectric layer using a halftone mask.

9. The method for manufacturing the array substrate having the capacitor according to claim 7, wherein in the step (3), patterning the interlayer dielectric layer further comprises forming a trench at a position corresponding to the lower electrode plate of the capacitor; and the step (4) further comprises forming the upper electrode plate of the capacitor within the trench.

10. The method for manufacturing the array substrate having the capacitor according to claim 7, wherein the first metal layer and the second metal layer are made of titanium, aluminum, molybdenum, or copper.

11. The method for manufacturing the array substrate having the capacitor according to claim 7, wherein the interlayer dielectric layer is made of silicon nitride, silicon dioxide, or a combination of silicon nitride and silicon dioxide.

12. The method for manufacturing the array substrate having the capacitor according to claim 7, wherein both the lower electrode plate of the capacitor and the upper electrode plate of the capacitor have a thickness ranging from 1000 Å to 5000 Å.

13. The method for manufacturing the array substrate having the capacitor according to claim 7, wherein the interlayer dielectric layer between the lower electrode plate of the capacitor and the upper electrode plate of the capacitor has a thickness ranging from 500 Å to 6000 Å.

14. The method for manufacturing the array substrate having the capacitor according to claim 7, wherein in the step (5), sequentially forming the planarization layer, the anode, the pixel defining layer, and the photoresist layer on the second metal layer further comprises:
coating an organic layer on the second metal layer and patterning the organic layer to form the planarization layer;
depositing an anode metal layer on the planarization layer and patterning the anode metal layer to form the anode; and
coating an organic photoresist layer on the anode and patterning the organic photoresist layer to form the pixel defining layer and the photoresist layer.

15. An array substrate having a capacitor, comprising:
a substrate;
a barrier layer, a buffer layer, and an active layer sequentially disposed on the substrate;
a gate insulation layer disposed on the active layer, wherein the gate insulation layer covers the active layer;
a gate electrode and a lower electrode plate of the capacitor disposed on the gate insulation layer;
an interlayer dielectric layer disposed on the gate electrode and the lower electrode plate of the capacitor, wherein the interlayer dielectric layer covers the gate electrode and the lower electrode plate of the capacitor;
a source and drain electrode and an upper electrode plate of the capacitor disposed on the interlayer dielectric layer, wherein the source and drain electrode is electrically connected to the active layer via a source and drain electrode contact hole, and the lower electrode plate of the capacitor and the upper electrode plate of the capacitor are insulated from each other by the interlayer dielectric layer;
a planarization layer, an anode, a pixel defining layer, and a photoresist layer sequentially disposed on the source and drain electrode and the upper electrode plate of the capacitor.

16. The array substrate having the capacitor according to claim 15, wherein a trench is included in the interlayer dielectric layer at a position corresponding to the lower electrode plate of the capacitor, and the upper electrode plate of the capacitor is disposed within the trench.

17. The array substrate having the capacitor according to claim 15, wherein the first metal layer and the second metal layer are made of titanium, aluminum, molybdenum, or copper.

18. The array substrate having the capacitor according to claim 15, wherein the interlayer dielectric layer is made of silicon nitride, silicon dioxide, or a combination of silicon nitride and silicon dioxide.

19. The array substrate having the capacitor according to claim 15, wherein both the lower electrode plate of the capacitor and the upper electrode plate of the capacitor have a thickness ranging from 1000 Å to 5000 Å.

20. The array substrate having the capacitor according to claim 15, wherein the interlayer dielectric layer between the lower electrode plate of the capacitor and the upper electrode plate of the capacitor has a thickness of ranging from 500 Å to 6000 Å.
